(19) United States
(12) Patent Application Publication
(10) Pub. No.: US 2013/0216954 A1
(43) Pub. Date: Aug. 22, 2013

(54) DRAWING APPARATUS, AND METHOD OF MANUFACTURING ARTICLE

(71) Applicant: CANON KABUSHIKI KAISHA, (US)

(72) Inventors: Satoru Oishi, Utsunomiya-shi (JP); Masato Muraki, Inagi-shi (JP); Koichi Sentoku, Kawachi-gun (JP); Wataru Yamaguchi, Utsunomiya-shi (JP); Hideki Ina, Tokyo (JP)

(73) Assignee: CANON KABUSHIKI KAISHA, Tokyo (JP)

(21) Appl. No.: 13/771,267

(22) Filed: Feb. 20, 2013

(30) Foreign Application Priority Data
Feb. 22, 2012 (JP) 2012-036765

(51) Int. Cl. H01J 37/317; G03F 7/26

(52) U.S. Cl. CPC H01J 37/3174; G03F 7/26
USPC 430/296; 250/492.3; 250/396 R

(57) ABSTRACT

A drawing apparatus, which draws a pattern on a substrate with a plurality of charged particle beams, includes: a charged particle optical system configured to emit the plurality of charged particle beams onto the substrate; and a controller configured to control an operation of the charged particle optical system. The controller is configured to control the operation so as to compensate for a distortion of the pattern that is determined based on first data of an undulation of a surface of the substrate and second data of an inclination of each of the plurality of charged particle beams with respect to an axis of the charged particle optical system.

### BACKGROUND OF THE INVENTION

1. Field of the Invention

The present invention relates to a drawing apparatus which draws a pattern on a substrate with a plurality of charged particle beams, and a method of manufacturing an article.

2. Description of the Related Art

When the device pattern of the (n+1)th layer (n is a natural number) is drawn on the device pattern of the nth layer with an electron beam in a semiconductor process, the device patterns of the nth and (n+1)th layers are aligned before drawing. For this alignment (overlay) operation, an alignment measurement operation is performed. In the alignment measurement operation, the positions of a plurality of alignment marks having already been formed on the wafer are measured using, for example, an off-axis alignment scope, and the positions of all shots (or some shots) having the patterns drawn on the wafer are obtained based on the measured values. In this way, the position of each shot on the wafer, in which the nth layer is formed, is obtained, and then this shot is moved to the electron beam drawing position to draw the device pattern of the (n+1)th layer on the pattern drawn in the nth layer in overlay.

To prevent the position of each electron beam on the wafer surface from shifting from the target position in the horizontal direction even if the position of the wafer surface shifts from the target position in the vertical direction, it is desired to guide this electron beam to be perpendicularly incident on the wafer. The perpendicularity in this case will also be referred to as the telecentric characteristics named after an (image-side) telecentric optical system, and the degree of perpendicularity will also be referred to as the telecentricity hereinafter.

In a drawing apparatus which uses a plurality of electron beams, the overlay precision may degrade as the telecentricity of each electron beam lowers. Japanese Patent Laid-Open No. 2005-109235 points out a problem that low telecentricity causes distortion in the drawn pattern, and proposes a drawing system which measures and corrects a shift corresponding to the distortion as a solution to this problem.

As disclosed in Japanese Patent Laid-Open No. 2005-109235, a method of correcting the shift of each electron beam in consideration of the telecentric characteristics has been proposed, but a method of correcting the shift of each electron beam in consideration of the flatness of a wafer when a predetermined pattern is drawn on the wafer has not yet been proposed. The inventor of the present invention conducted an examination, and found that the actual flatness of the wafer was about 1 μm. The product of the flatness (1 μm in this case) and the telecentricity (1 mRad in this case) is 1 nm, so the electron beam may shift by about 1 nm on the wafer. The overlay precision required for the drawing apparatus is, for example, about ¼ of the minimum line width (for example, about 5 nm when the line width is 20 nm). At this time, the above-mentioned example of the numerical value of the product of the flatness (the amount of defocus associated with it) and the telecentricity, that is, 1 nm is non-negligible.

The wafer flatness is set to a value of 1 μm or less in each shot by flattening the wafer by, for example, the CMP process in, for example, an immersion exposure apparatus with a small depth of focus. However, to improve the wafer flatness, the total cost of the semiconductor manufacture increases.

On the other hand, in a drawing apparatus which uses a plurality of electron beams, setting the standard of the telecentricity of each electron beam as strict as, for example, 0.5 mRad or less leads to an increase in component cost or adjustment cost of the drawing apparatus, if not impossible. As a result, the total cost of the semiconductor manufacture increases as well.

### SUMMARY OF THE INVENTION

The present invention provides, for example, a drawing apparatus advantageous in terms of overlay precision.

The present invention provides a drawing apparatus which draws a pattern on a substrate with a plurality of charged particle beams, the apparatus comprising: a charged particle optical system configured to emit the plurality of charged particle beams onto the substrate; and a controller configured to control an operation of the charged particle optical system, wherein the controller is configured to control the operation so as to compensate for a distortion of the pattern that is determined based on first data of an undulation of a surface of the substrate and second data of an inclination of each of the plurality of charged particle beams with respect to an axis of the charged particle optical system.

Further features of the present invention will become apparent from the following description of exemplary embodiments with reference to the attached drawings.

### BRIEF DESCRIPTION OF THE DRAWINGS

FIG. 1 is a flowchart showing a drawing method according to the first embodiment;

FIG. 2 is a view showing a drawing apparatus;

FIGS. 3A and 3B are views for explaining baseline measurement;

FIG. 4 is a view for explaining an electron beam deflection operation;

FIG. 5 is a view showing a map of the telecentricity of each electron beam;

FIG. 6 is a view showing the information of the wafer flatness;

FIG. 7 is a view showing a position shift amount generated on the wafer surface;

FIG. 8 is a graph showing the relationship among the telecentricity, the wafer flatness, and the position shift amount;

FIG. 9 is a flowchart showing a step of correcting drawing data;

FIG. 10 is a view showing the relationship between a data grid and a beam grid;

FIG. 11 is a view showing the relationship between the data on the beam grid, and the drawing range on the data grid;

FIG. 12 is a view illustrating an example of the result of correcting drawing data; and

FIG. 13 is a flowchart showing a drawing method according to the fourth embodiment.

### DESCRIPTION OF THE EMBODIMENTS

### First Embodiment

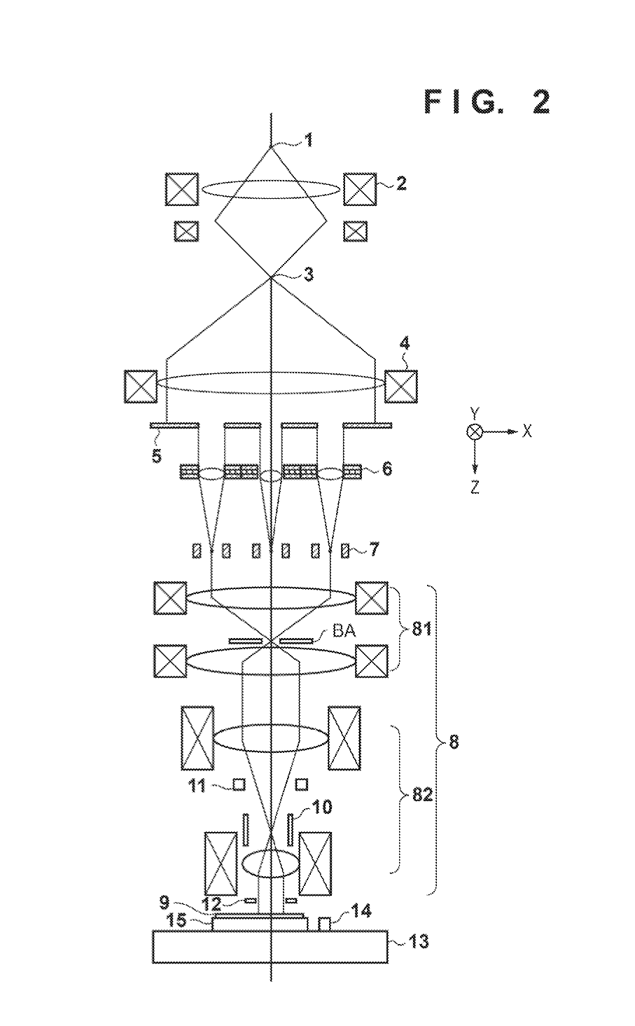

Although the present invention is applicable to a drawing apparatus which draws a pattern on a substrate with a plurality of charged particle beams, an example in which the present invention is applied to a drawing apparatus which uses a plurality of electron beams will be described hereinafter. FIG. 2 is a schematic view showing the configuration of a drawing apparatus which uses a plurality of electron beams. Referring to FIG. 2, an electron beam emitted by an electron source 1 forms an image 3 of the electron source 1 via an optical system 2 which shapes it. The electron beam from the image 3 is converted into a nearly collimated electron beam by a collimator lens 4. The nearly collimated electron beam passes through an aperture array 5. The aperture array 5 includes a plurality of apertures and splits an incident electron beam into a plurality of electron beams. The plurality of electron beams split by the aperture array 5 form intermediate images of the image 3 by an electrostatic lens array 6 in which a plurality of electrostatic lenses are formed. A blanker array 7 in which a plurality of blankers are formed as electrostatic deflectors is located on the intermediate image plane.

An electron optical system (charged particle optical system) 8 implemented by two-step symmetric magnetic doublet lenses 81 and 82 is located downstream of the intermediate image plane, and a plurality of intermediate images are projected onto a wafer (substrate) 9. The electron optical system 8 has an axis in the Z-direction, and emits a plurality of electron beams onto the substrate. The Z-direction is parallel to the axis of the electron optical system 8. An electron beam deflected by the blanker array 7 is blocked by a blanking aperture BA, and therefore does not strike the wafer 9. On the other hand, an electron beam which is not deflected by the blanker array 7 is not blocked by the blanking aperture BA, and therefore strikes the wafer 9. The lower doublet lens 82 accommodates deflectors 10 for simultaneously displacing a plurality of electron beams to a target drawing position in the X- and Y-directions, and a focusing coil 12 for simultaneously adjusting the focuses of the plurality of electron beams. A wafer stage 13 holds the wafer 9 and is movable in the X- and Y-directions perpendicular to the axis of the electron optical system 8. An electrostatic chuck 15 for fixing the wafer 9 is placed on the wafer stage 13. The shape of each electron beam at a position defined on the irradiation surface of the wafer 9 is measured by a detector 14 including knife edges. An astigmatism meter 11 adjusts the astigmatism of the electron optical system 8.

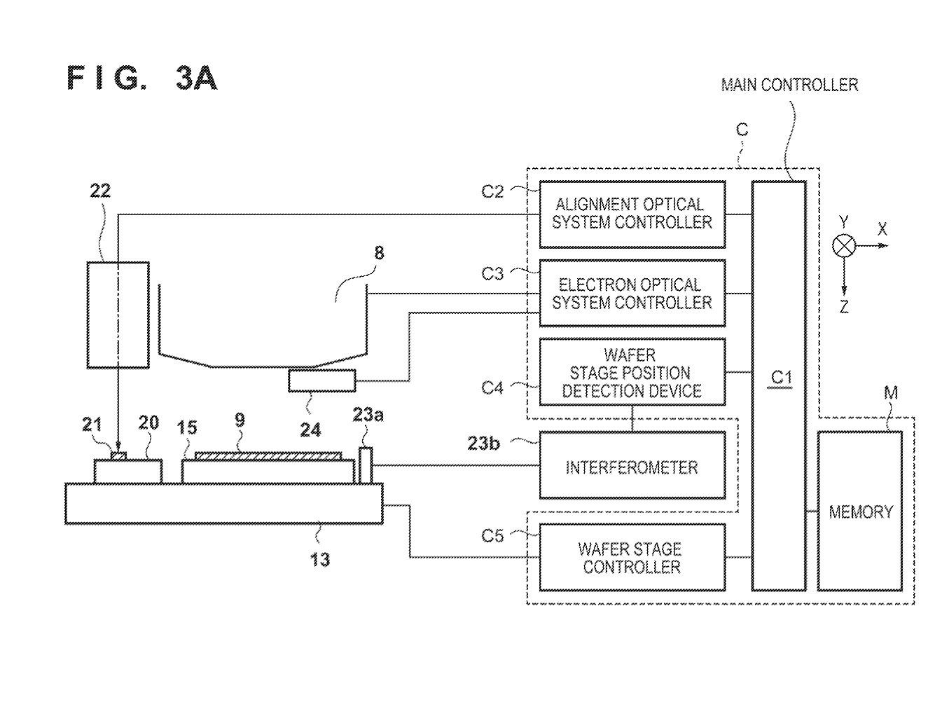

The wafer stage 13 moves by a step-and-repeat or step-and-scan operation, and a pattern is drawn in a plurality of shot regions on the wafer 9 with the electron beams while they are deflected simultaneously with the movement operation. In drawing a pattern on the wafer 9 while deflecting the electron beams, it is necessary to measure an electron beam reference position relative to the wafer stage 13. An electron beam reference position is measured using an off-axis alignment scope and electron beams in the following way. FIGS. 3A and 3B are enlarged views of the portion surrounding the wafer 9 in the drawing apparatus shown in FIG. 2.

Referring to FIG. 3A, a reference mark table 20 is placed on the wafer stage 13, and a reference mark 21 is formed on the reference mark table 20. An image of the reference mark 21 is detected by an off-axis alignment scope 22, and an image signal is processed by an alignment scope controller or alignment optical system controller C2, thereby specifying the position of the reference mark 21 relative to the optical axis of the alignment scope 22. At this time, a position P1 of the wafer stage 13 measured by an interferometer 23b including a mirror 23a placed on the wafer stage 13 is stored in a memory M via a main controller C1. The interferometer 23b serves as one detector which detects the position of the wafer stage 13 in the X- and Y-directions perpendicular to the Z-direction of the wafer stage 13 and the axis of the electron optical system 8.

As shown in FIG. 3B, the reference mark 21 is moved to an electron beam drawing position by a wafer stage controller C5, and the position of the reference mark 21 is detected by the electron beam using a wafer stage position detection device C4. The wafer stage controller C5 moves the position of the reference mark 21 to the vicinity of the electron beam drawing position. The main controller C1 uses the electron beam to measure a position P2 of the reference mark 21 formed on the reference mark table 20. In the first embodiment, the position P2 is specified by detecting secondary electrons, reflected by the reference mark 21, using an electron beam detector 24 while scanning the wafer stage 13. Based on the difference between the positions (coordinate positions) of the wafer stage 13 when the positions P1 and P2 are detected, the main controller C1 measures a baseline BL, that is, the difference between the position on the wafer 9, at which measurement is performed by the alignment scope 22, and that on the wafer 9, at which drawing is performed with the electron beam. The main controller C1, the alignment optical system controller C2, and an electron optical system controller C3, for example, constitute a controller C which controls the operation of the electron optical system 8.

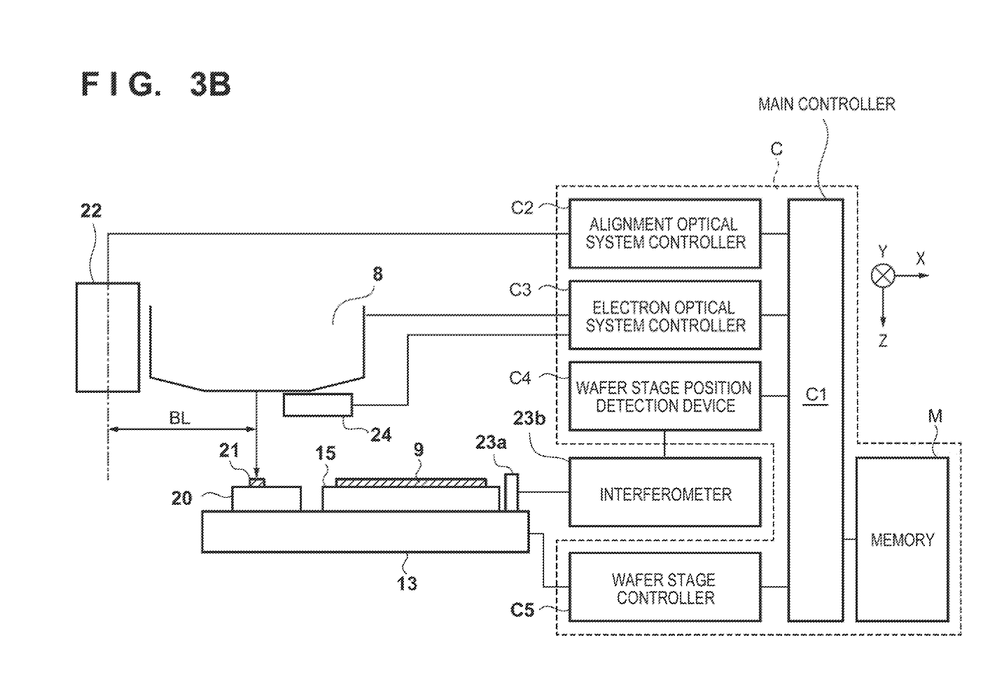

An electron beam deflection operation will be described with reference to FIG. 4. Assume herein that the X-direction is defined as a main deflection direction, and the Y-direction is defined as a sub-deflection direction. Assume also that m electron beams are juxtaposed in the X-direction, and n electron beams are juxtaposed in the Y-direction. First, the X- and Y-deflectors 10, and the wafer stage 13 are controlled so that an upper left drawing grid 501 in a drawing area 500 of each electron beam is irradiated with this electron beam. Note that upon driving of the blanker array 7, the drawing grid 501 is irradiated with the electron beam for a predetermined time specified for each drawing grid 501 based on drawing data to perform drawing. As the electron beam is scanned on the substrate step by step in the main deflection (X) direction by the X-deflector 10, each drawing grid is sequentially drawn.

After drawing on one row is completed, the electron beam returns to the left end in the X-direction, and drawing starts on the next row. At this time, the wafer stage 13 moves at a constant speed in the sub-deflection (Y) direction. The Y-deflector 10 adjusts the amount of deflection while following the movement of the wafer stage 13. After drawing on one row is completed, the position of the electron beam in the Y-direction returns to the initial position for drawing on the next row. Therefore, the Y-deflector 10 can deflect the electron beam at a grid width corresponding to one row. By repeating this operation, drawing can be performed over the entire drawing area 500. The electron beam drawing apparatus must evacuate the drawing environment to a vacuum in order to avoid attenuation of the electron beam for drawing. Hence, to measure the flatness of the wafer 9 inside the drawing apparatus, it is necessary to measure this flatness in a vacuum as well. As a method of measuring the flatness of the wafer 9, a method which uses, for example, light triangulation (oblique incidence & image shift scheme) or a capacitance sensor is available. This measurement method is not particularly limited to specific examples as long as it can be done in a vacuum.

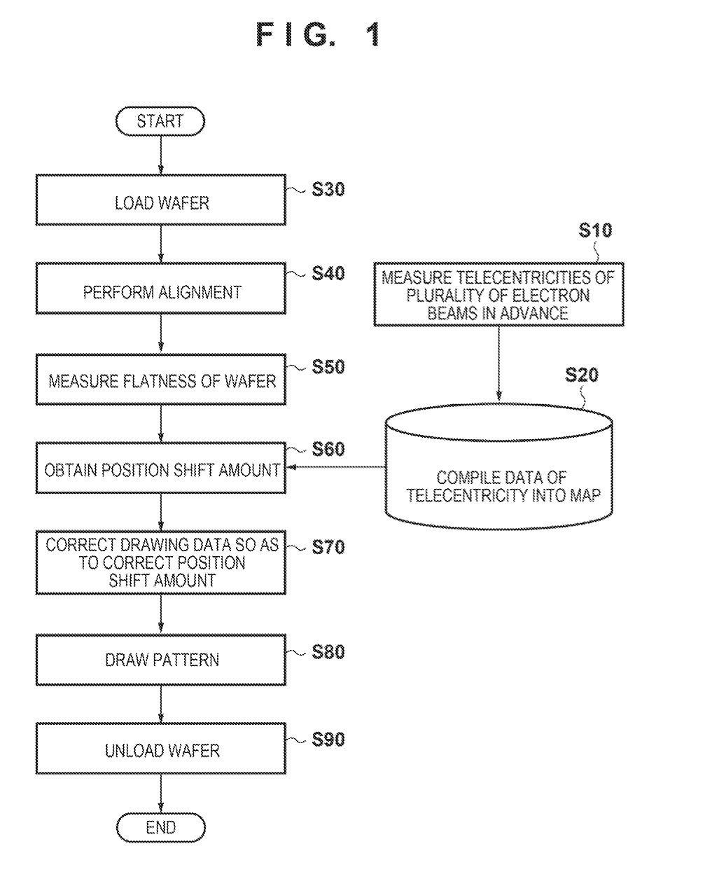

FIG. 1 is a flowchart showing the sequence of a drawing method according to the first embodiment. First, in step S10, the telecentricity of each of a plurality of electron beams is measured in advance before drawing. Note that the telecentricity means the degree of perpendicularity of each electron beam, and indicates the degree of inclination (angle of inclination) of each electron beam with respect to the axis of the electron optical system 8.

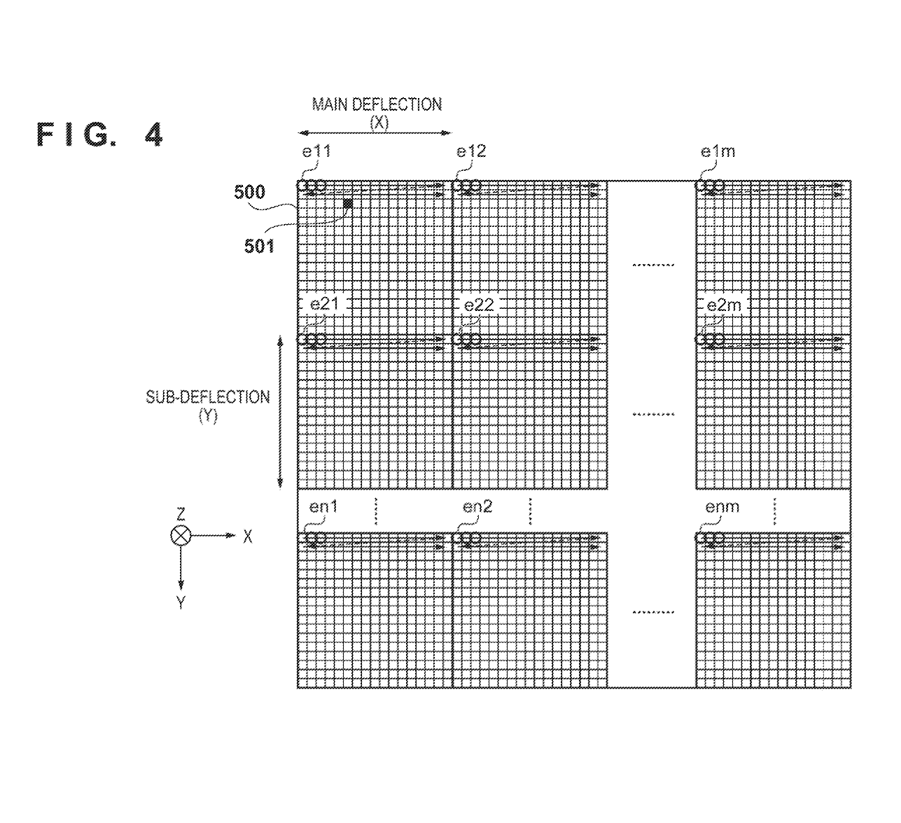

In step S20, the main controller C1 compiles, into a map, a database of data of the telecentricity measured in step S10, and stores it in the memory M. A practical example of the telecentricity map obtained in step S20 will be described. FIG. 5 is a view showing a map of the telecentricity of each of a plurality of electron beams in a given shot region S1 on the wafer 9. FIG. 5 shows a map of the telecentricity of each of a total of m(X-direction)×n(Y-direction)=mn electron beams. For example, the telecentricity of an electron beam eij is represented by (θx_ij, θy_ij). Note that θx_ij and θy_ij represent the telecentricities of the electron beam eij in the X- and Y-directions, respectively. The interval between adjacent electron beams is equal to the width of the drawing area 500 shown in FIG. 4, and is defined as Lx in the X-direction and as Ly in the Y-direction.

In step S30 of FIG. 1, a wafer 9 is loaded onto the wafer stage 13, and prealignment is performed to allow alignment first. In step S40, the wafer 9 is aligned using the off-axis alignment scope 22. In this embodiment, global alignment is performed in step S40.

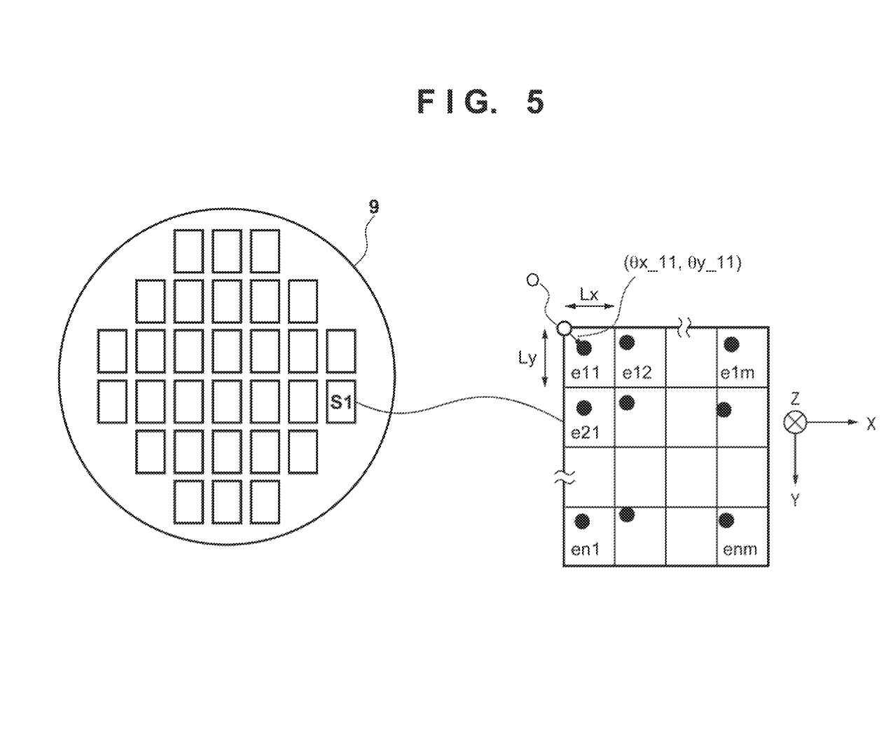

In step S50, the flatness or surface shape (surface undulation) of the wafer 9, that is, the position, in the Z-direction, of each point (each measurement point) on the surface of the wafer 9 is measured. This measurement operation can be performed by any known measurement device as long as a required measurement precision can be obtained. FIG. 6 is a view schematically showing the flatness of the wafer 9. For the sake of convenience, the direction of a vector indicates the direction of flatness, and the magnitude of the vector indicates the degree of flatness. The flatness is obtained at pitches equivalent to the intervals Lx and Ly between a plurality of electron beams, and is ΔZ_ij in the portion corresponding to the electron beam eij in the shot region S1. Although the flatness control resolution is equivalent to the intervals between adjacent electron beams in this embodiment, there is no need to measure the flatness at pitches equivalent to the intervals between adjacent electron beams. The flatness of the wafer 9 may be measured at pitches larger than the intervals between adjacent electron beams, interpolated by these beam intervals, and used.

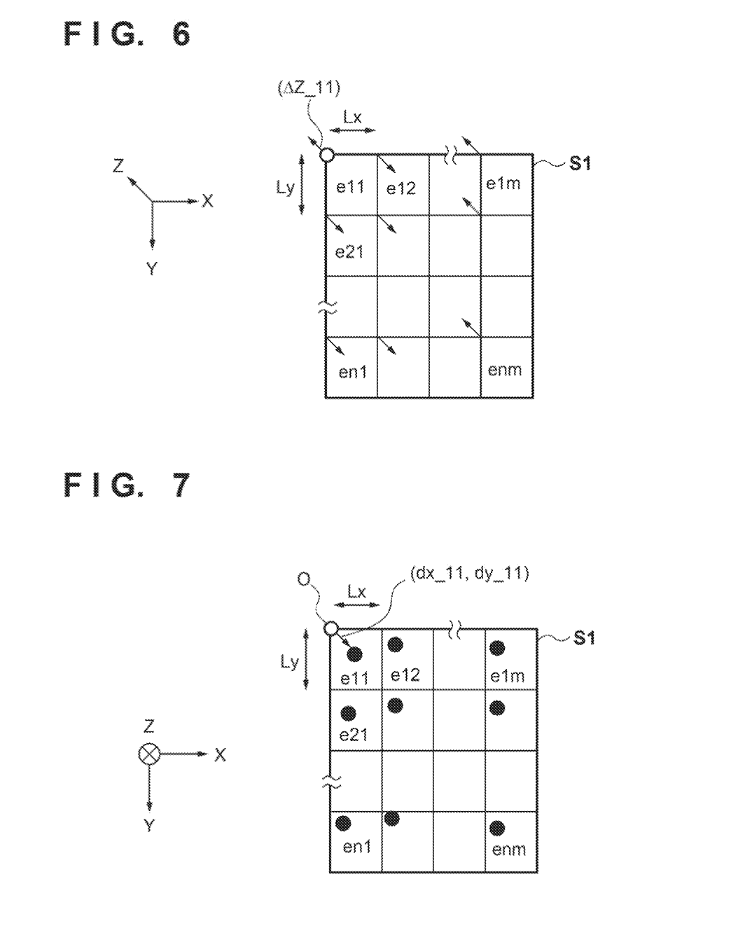

In step S60 of FIG. 1, the main controller C1 obtains the position shift amount of each electron beam on the surface of the wafer 9, based on the telecentricity map stored in the memory M, and the data of the flatness measured in step S140. FIG. 7 is a view showing a position shift amount generated on the surface of the wafer 9, which is obtained from the value of the product of the telecentricity and flatness of each electron beam. For example, the position shift amount, that is, the correction amount of the drawing position of the electron beam eij is represented by (dx_ij, dy_ij) (i=1, . . . , n, j=1, . . . , m).

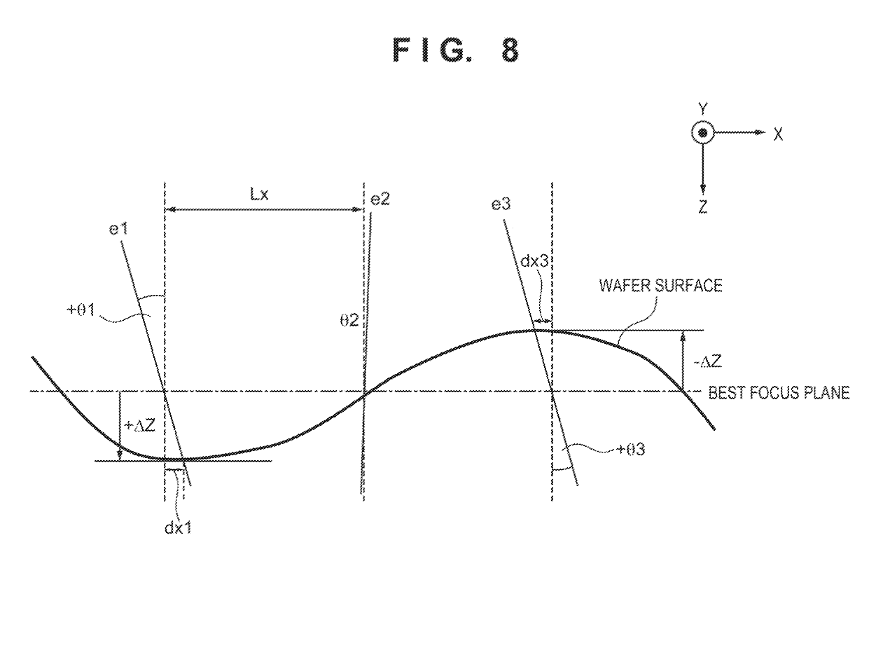

A method of actually obtaining the position shift amount (dx_ij, dy_ij) on the wafer 9 based on the telecentricity of each electron beam, and the flatness of the wafer 9 will be described. FIG. 8 is a graph showing the relationship among the telecentricities of three electron beams, the flatness of the wafer 9, and the shift amount of the drawing position of each electron beam. The position shift in the X-direction alone will briefly be described herein. Let θi be each electron beam, Lx be the interval between adjacent electron beams, θi (the counterclockwise direction is defined as the positive direction) be the telecentricity of this electron beam θi, ΔZ (the downward direction on the paper surface of FIG. 8 is defined as the positive direction) be the shift amount of the flatness of the wafer 9, and dxi be the shift amount of the drawing position. Note that referring to FIG. 8, the position shift of each electron beam θi on a best focus plane has already been corrected. To determine a best focus plane, various methods are available, including a method of obtaining a best focus plane by least-squares approximation for the data on the wafer surface so as to minimize the RMS value, and a method of determining a plane which minimizes the maximum value of the difference from each data on the wafer surface so as to eliminate any portion with too much defocusing.

Referring to FIG. 8, the electron beam e1 has a telecentricity +θ1, and drawing is performed at a position +ΔZ from the best focus plane of the wafer 9. The shift amount d×1 of the drawing position of the electron beam e1 on the wafer 9 is given by:

d×1=θ1×ΔZ (1)

The electron beam e3 has a telecentricity +θ3, and drawing is performed at a position −ΔZ from the best focus plane of the wafer 9. Therefore, the shift amount d×3 of the drawing position of the electron beam e3 on the wafer 9 is given by:

d×3=−θ3×ΔZ (2)

The electron beam e2 has a high telecentricity θ2, and the flatness of the wafer 9 is that nearly corresponding to a best focus, so the shift amount d×2 of the drawing position on the wafer 9 is small. Although the shift amount of the drawing position in the X-direction has been described with reference to FIG. 8, the shift amount of the drawing position on the wafer in the Y-direction can also be obtained using the same method.

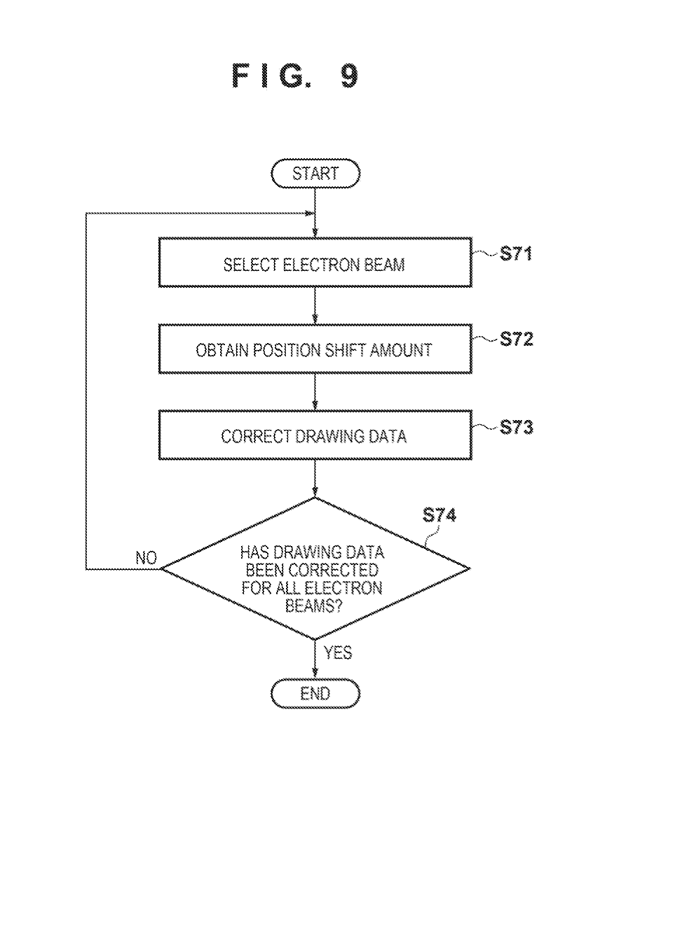

In step S70 of FIG. 1, the main controller C1 corrects and changes drawing data generated in advance so as to correct the shift amount of the drawing position obtained in step S60. FIG. 9 is a flowchart showing details of a step of correcting drawing data in step S70. When one deflector collectively controls a plurality of electron beams ell to enm, their deflection cannot be controlled individually. Therefore, a drawing error must be reduced by individually calculating the shift amount of the drawing position for each of the plurality of electron beams, and correcting the drawing data.

In step S71, the main controller C1 selects one of the plurality of electron beams. In step S72, the main controller C1 obtains the shift amount of the drawing position, which is required to correct the drawing position of the selected electron beam. In this embodiment, the shift amount, and the rotation error and magnification error upon deflection are assumed to be uniquely determined especially in the X- and Y-deflection ranges Lx and Ly of the same electron beam.

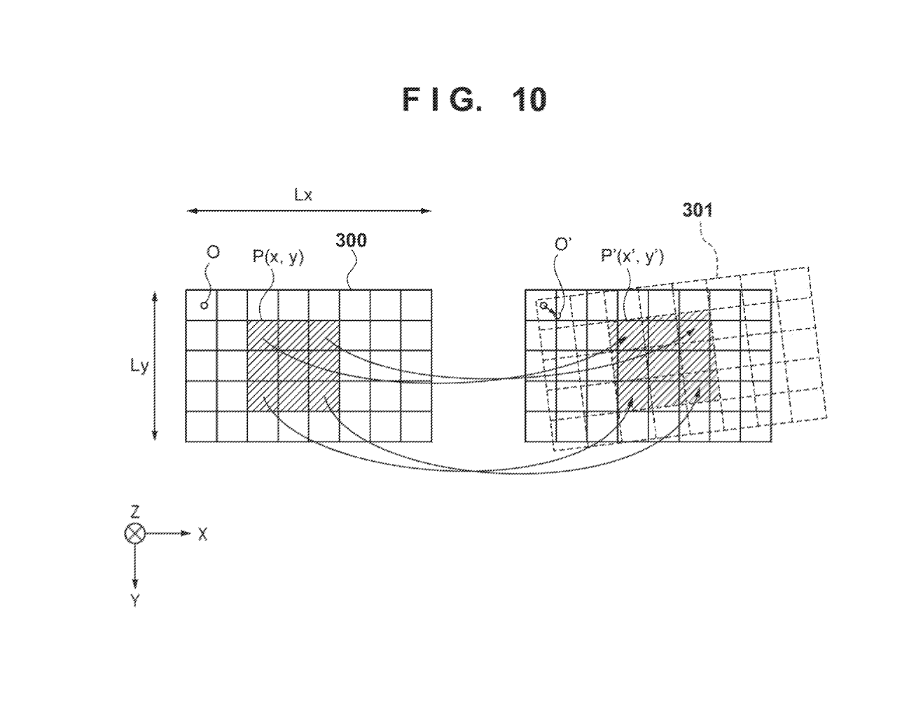

FIG. 10 shows blanker data, that is, a data grid 300 in one selected electron beam (for example, the electron beam e11), and a beam grid 301 when drawing is actually performed on the wafer 9. A double-headed arrow in FIG. 10 shows an example in which data on the data grid 300 is drawn on the beam grid 301 upon deflecting the electron beam e11. An origin O when the electron beam e11 is not deflected is drawn at a coordinate position O′ on the beam grid 301. Note that the amount of shift from the origin O to the coordinate position O′ is the above-mentioned shift amount of the drawing position calculated from the product of the telecentricity of the electron beam and the flatness of the wafer 9, and corresponds to (dx_11, dy_11). Although the origin O is shown on the upper left corner in the deflection ranges Lx and Ly, it may be set at the center of the deflection range Lx. When the drawing data is not corrected, given data P on the data grid 300 is drawn at a coordinate position P′ on the beam grid 301, so a desired pattern (a 3×3 hole pattern in this case) cannot be drawn.

The coordinate position P′(x′, y′) on the beam grid 301 is given by:

$$( \begin{matrix}{x}^{′} \\ {y}^{′}\end{matrix} ) = ( \begin{matrix}dx \\ dy\end{matrix} ) + ( \begin{matrix}mx cos θ x & - mx sin θ y \\ mx sin θ x & my cos θy\end{matrix} ) ( \begin{matrix}x \\ y\end{matrix} ) \qquad ( 3 )$$

where dx and dy are the shift components of the electron beam, mx and my are the magnification components of the electron beam upon deflection, and ex and θy are the rotation components of the electron beam upon deflection.

In general, x′ and y′ are expressed as linear equations for x and y as per:

x′=a1x+b1y+dx

y′=a2x+b2y+dy (4)

Note that equations (4) are not limited to linear equations for x and y, and can also be expressed as polynomials for x and y.

The shift components dx and dy indicate the shift amount of the drawing position calculated from the telecentricity of the electron beam eij and the flatness ΔZ of the wafer 9, and are given by:

dx=dx_{—}ij

dy=dy_{—}ij (5)

It is often difficult to set not only the shift components (dx_ij, dy_ij) due to the telecentricity of the electron beam and the flatness of the wafer 9, but also the shift amount of the electron beam eij of itself to zero. Letting (dx0_ij, dy0_ij) be the shift amount of the electron beam eij of itself, the shift amounts dx and dy of the drawing position are calculated by:

dx=dx0_{—}ij+dx_{—}ij

dy=dy0_{—}ij+dy_{—}ij (6)

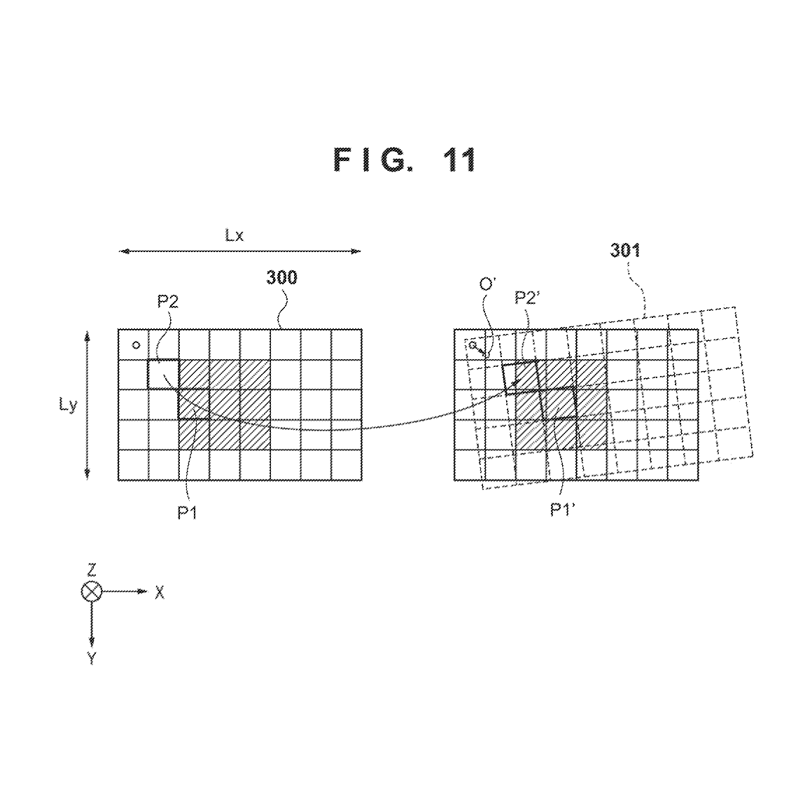

Referring back to FIG. 9, in step S73, the main controller C1 corrects and changes the drawing data using the shift amount of the drawing position given by, for example, the above-mentioned equations (4). FIG. 11 is a view showing the positional relationship between data P′ on the beam grid 301, and the original data grid 300. For the sake of simplicity, all of 3×3 data of the beam grid 301 serve as data of electron beam intensities having a duty ratio of 1. For example, the data P1 on the data grid 300 is drawn as data P1′ of the beam grid 301 on the wafer. All the data P1′ fall within the drawing region of the original data grid, so the drawing data is drawn at electron beam intensities having a duty ratio of 1.

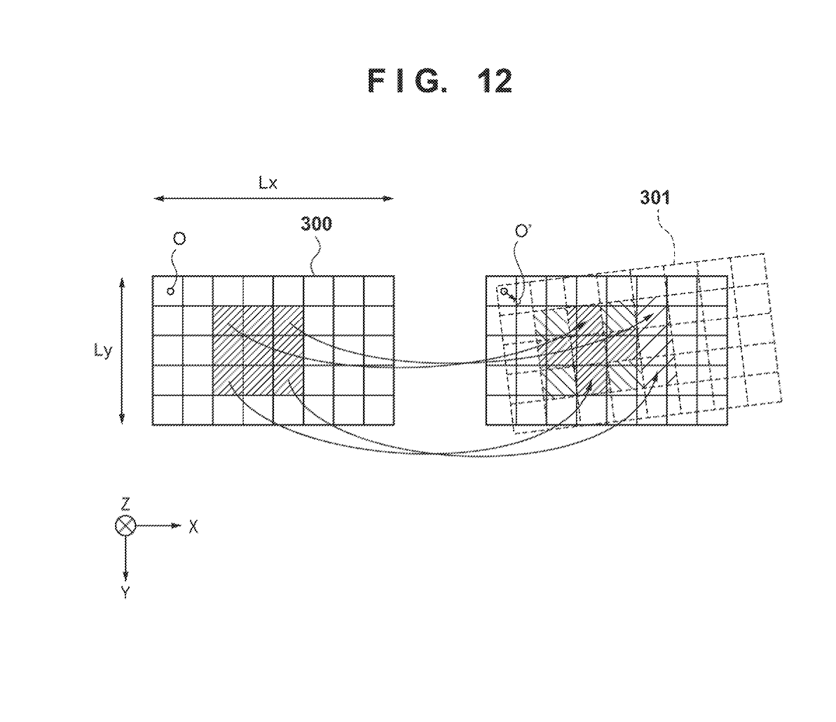

On the other hand, the data P2 on the data grid 300 is drawn as data P2′ upon the beam grid 301 on the wafer, and extends across the region in which the original drawing pattern is drawn and that in which this pattern is not drawn. In this case, the duty ratio is calculated and corrected from the ratio of the area of periphery data to the original data grid within the region of the data P2′. If, for example, the drawing region is 60% and the non-drawing region is 40%, the drawing data is corrected to electron beam intensities having a duty ratio of 0.6. As a method of interpolating the drawing data from periphery data, linear interpolation of four pixels on the original data grid 300, which surround an arbitrary coordinate position P′(x′, y′) on the beam grid 301, may be performed. Alternatively, the drawing data may be corrected by bicubic interpolation using 16 surrounding pixels. FIG. 12 shows an example of the result of correcting the drawing data on the beam grid 301. The drawing data of the beam grid 301 is obtained from that of the data grid 300 while correcting the electron beam intensity of the electron beam e11.

In the correction operation of the drawing data in step S73 of FIG. 9, it is determined whether the drawing data is corrected for all electron beams in step S74. If NO is determined in step S74, the process returns to step S71, and steps S72 and S73 are then repeated. For example, the shift components indicating the shift amount of the drawing position obtained from the telecentricity and the flatness of the wafer 9 for the electron beam e12 different from the electron beam ell become dx_12 and dy_12, which are different from those of the electron beam e11. Therefore, the drawing data of the beam grid 301 is similarly corrected for the electron beam e12 using the shift components dx_12 and dy_12 of the drawing position. In this way, the drawing data is corrected for all the electron beams ell to enm.

Referring back to FIG. 1, in step S80, the main controller C1 draws a pattern based on the corrected drawing data. In step S90, the wafer having the pattern drawn on it is unloaded, and the sequence of drawing ends.

As described above, in this embodiment, it is possible to correct the shift components, and the rotation error and magnification error upon deflection, in consideration of the telecentricity of the electron beam and the flatness of the wafer 9, thus improving the drawing precision. In this embodiment, a plurality of electron beams are collectively deflected, the shift components of the drawing data are corrected based on the shift amount of the drawing position based on the telecentricity and the flatness of the wafer 9, and drawing is performed based on the corrected drawing data. When deflectors are provided in correspondence with a plurality of electron beams, the above-mentioned position shift amount can be compensated for by changing a command to the deflector set for each electron beam.

Also, when a plurality of electron beams are divided into several sub-arrays, and a deflector is used for each sub-array, drawing may be performed by controlling the deflector for each sub-array upon regarding the wafer 9 within the sub-array region to have a uniform flatness. Although the flatness of the wafer 9 is measured for the entire surface of the wafer 9 at once in FIG. 1, the present invention is not limited to this. For example, before drawing in a given shot region, it is possible to measure the flatness of the shot region in which a pattern is to be drawn alone, correct the drawing data in the shot region, and perform drawing. Although global alignment is used in the alignment operation of step S40, the present invention is not limited to this. The object of the present invention can also be achieved by dye-by-dye alignment, in which alignment is performed before drawing in each shot region.

By the drawing operation using the above-mentioned method, a drawing apparatus which uses a plurality of charged particle beams can attain a high overlay precision even if an inexpensive process which uses low standards for both the telecentricity of each charged particle beam and the flatness of the wafer 9. This makes it possible to provide a drawing apparatus and drawing process with a high CoO (Cost of Ownership).

### Second Embodiment

The information of the flatness of a wafer 9 can also be obtained using a measurement device other than a drawing apparatus if it is possible to predict the flatness of the wafer 9 during drawing. In this case, there is no need to compensate for attenuation of the electron beam, so the flatness of the wafer 9 can be measured in atmospheric air using, for example, the air focusing method.

### Third Embodiment

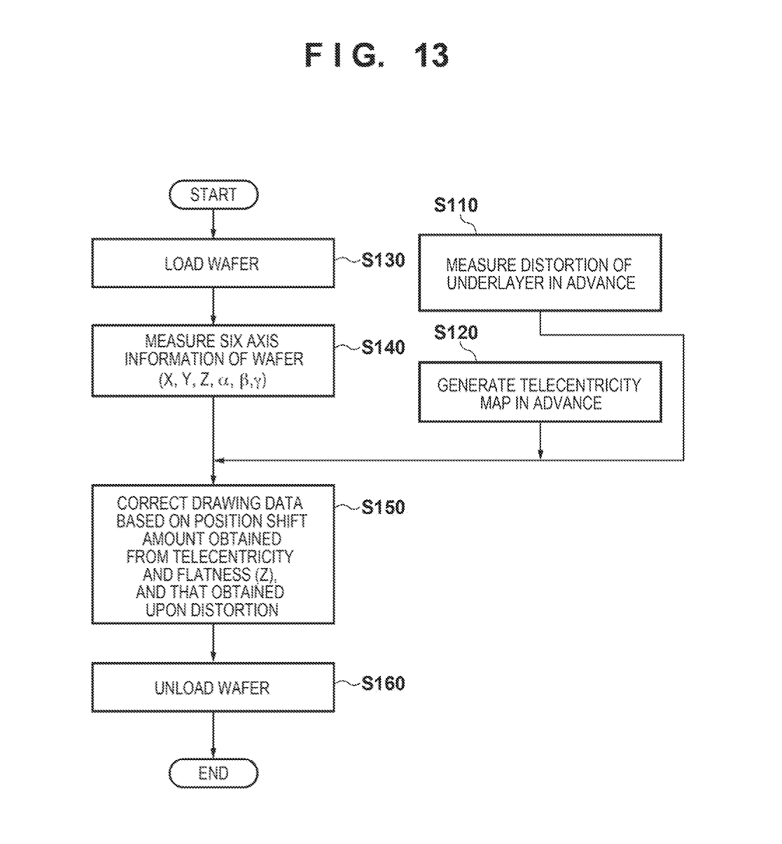

In the third embodiment, if the shift (distortion) of a pattern formed on the underlayer of a wafer from a target position is determined in advance, drawing is performed in consideration of this shift. The third embodiment will be described with reference to a flowchart shown in FIG. 13. In step S120, a telecentricity map is generated in advance, while the distortion of the underlayer is measured in advance in step S110. In step S130, a wafer 9 is loaded onto a wafer stage 13, and wafer alignment and focus measurement are performed in step S140 to measure six axis data (X, Y, Z, α, β, γ). Of the measured six axis data of the wafer 9, the data of the Z-axis serves as that of the flatness of the wafer 9. In step S150, a main controller C1 performs drawing upon correcting the drawing data based on the shift amount of the drawing position obtained using the telecentricity map and the data of the flatness of the wafer 9, described in the first embodiment, and that of the drawing position upon the distortion measured in step S110. More specifically, in step S150, the main controller C1 sums the shift amount obtained using the telecentricity map and the data of the flatness of the wafer 9, and that upon the distortion, and corrects the drawing data based on the summed shift amount.

[Method of Manufacturing Article]

A method of manufacturing an article according to an embodiment of the present invention is suitable for manufacturing various articles including a microdevice such as a semiconductor device and an element having a microstructure. This method can include a step of forming a latent image pattern on a photosensitive agent, applied on a substrate, using the above-mentioned drawing apparatus (a step of performing drawing on a substrate), and a step of developing the substrate having the latent image pattern formed on it in the forming step. This method can also include subsequent known steps (for example, oxidation, film formation, vapor deposition, doping, planarization, etching, resist removal, dicing, bonding, and packaging). The method of manufacturing an article according to this embodiment is more advantageous in terms of at least one of the performance, quality, productivity, and manufacturing cost of an article than the conventional method.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2012-036765 filed Feb. 22, 2012, which is hereby incorporated by reference herein in its entirety.

What is claimed is:

1. A drawing apparatus which draws a pattern on a substrate with a plurality of charged particle beams, the apparatus comprising:
a charged particle optical system configured to emit the plurality of charged particle beams onto the substrate; and
a controller configured to control an operation of the charged particle optical system,
wherein the controller is configured to control the operation so as to compensate for a distortion of the pattern that is determined based on first data of an undulation of a surface of the substrate and second data of an inclination of each of the plurality of charged particle beams with respect to an axis of the charged particle optical system.

2. The apparatus according to claim 1, wherein the controller is configured to control the operation so as to compensate for the distortion of the pattern relative to a pattern having been formed on the substrate.

3. The apparatus according to claim 1, wherein the controller is configured to change drawing data, to be given to the charged particle optical system, based on a position of each of the plurality of charged particle beams on the substrate that is determined based on the first data and the second data.

4. The apparatus according to claim 1, wherein
the charged particle optical system includes a plurality of deflectors configured to respectively deflect the plurality of charged particle beams to respectively scan the plurality of charged particle beams on the substrate, and
the controller is configured to change commands for the plurality of deflectors based on a position of each of the plurality of charged particle beams on the substrate that is determined based on the first data and the second data.

5. The apparatus according to claim 1, further comprising a measurement device configured to measure the undulation.

6. A method of manufacturing an article, the method comprising:
performing drawing on a substrate using a drawing apparatus;
developing the substrate having undergone the drawing; and
processing the developed substrate to manufacture the article,
wherein the drawing apparatus draws a pattern on the substrate with a plurality of charged particle beams, the apparatus including:
a charged particle optical system configured to emit the plurality of charged particle beams onto the substrate; and
a controller configured to control an operation of the charged particle optical system,
wherein the controller is configured to control the operation so as to compensate for a distortion of the pattern that is determined based on first data of an undulation of a surface of the substrate and second data of an inclination of each of the plurality of charged particle beams with respect to an axis of the charged particle optical system.
